(19) United States
(12) Patent Application Publication
(10) Pub. No.: US 2009/0017619 A1
(43) Pub. Date: Jan. 15, 2009

(54) METHOD FOR MANUFACTURING METAL SILICIDE LAYER IN A SEMICONDUCTOR DEVICE

(76) Inventors: Young Jin LEE, Gyeonggi-do (KR); Baek Mann KIM, Gyeonggi-do (KR); Soo Hyun KIM, Seoul (KR); Dong Ha JUNG, Gyeonggi-do (KR); Jeong Tae KIM, Gyeonggi-do (KR); Hyeong Tag JEON, Seoul (KR); Keun Woo LEE, Seoul (KR); Keun Jun KIM, Gyeonggi-do (KR); Tae Yong PARK, Gyeonggi-do (KR)

Correspondence Address: LADAS & PARRY LLP, 224 SOUTH MICHIGAN AVENUE, SUITE 1600, CHICAGO, IL, 60604, US

(21) Appl. No.: 12/169,790

(22) Filed: Jul. 9, 2008

(30) Foreign Application Priority Data
Jul. 10, 2007 (KR) 10-2007-0069034

(51) Int. Cl. H01L 21/44

(52) U.S. Cl. 438/664; 257/E21.165

(57) ABSTRACT

A metal suicide layer is fabricated in a semiconductor device. A first metal layer is deposited on a silicon substrate formed with an S interlayer dielectric having a contact hole through PVD. A second metal layer is deposited on the first metal layer through any one of CVD and ALD. Annealing is performed on the silicon substrate which is formed with the first and second metal layers to form the metal silicide. The portions of the second metal layer and the first metal layer which have not reacted during annealing are removed.

### CROSS-REFERENCE TO RELATED APPLICATIONS

The present application claims priority to Korean patent application number 10-2007-0069034 filed on Jul. 10, 2007, which is incorporated herein by reference in its entirety.

### BACKGROUND OF THE INVENTION

The present invention relates to a method for manufacturing a semiconductor device, and more particularly to a method for manufacturing a semiconductor device that can form a stable metal silicide layer.

In order to realize a highly integrated semiconductor device, it is essential to secure stable contacts between upper and lower patterns. The reliability and the high speed operation of a semiconductor device cannot be ensured unless these contacts are stable between the lower and upper patterns.

As these semiconductor devices become more compact, the size of the contact holes become more diminutive which can result in the contact resistances being increased. If the contact resistance increases, the reliability and the high speed operation of the semiconductor device can be adversely compromised.

Identifying a suitable fabrication method that can be used to manufacture low resistance contacts would be highly desirable to compensate for some of the difficulties associated with building highly integrated semiconductor devices. One way of achieving this would be to develop a fabrication method that selectively forms a low resistance metal silicide in an area where an upper pattern and a lower pattern are brought into contact with each other.

A conventional method for forming a metal silicide layer will be schematically described. After depositing an interlayer dielectric on a silicon substrate having a transistor, a contact hole is formed by etching through the interlayer dielectric. The contact hole exposes the silicon substrate and delimits an area for forming a metal silicide layer. A metal layer, for example, a cobalt layer is then deposited on the interlayer dielectric having the contact hole as the area for forming a metal silicide layer. The metal layer may be deposited by any number of the well known deposition techniques such as PVD (physical vapor deposition), CVD (chemical vapor deposition) or ALD (atomic layer deposition).

Subsequent to depositing the metal layer, the metal layer is then annealing on the silicon substrate to form a metal silicide layer. This metal silicide layer is selectively formed on a portion of the silicon substrate which constitutes the bottom of the contact hole.

As the design of semiconductor devices has become more highly integrated, the aspect ratio of the contact holes in these highly integrated semiconductor devices correspondingly increases. Accordingly using PVD to deposit sufficient amounts of metal layers deep inside these high aspect ratio contact holes using conventional methods to eventually form metal silicide layers in these contact holes is becoming more difficult to achieve. That is, using conventional PVD deposition techniques step coverage deteriorates and therefore the amount of the metal layer deposited at the bottom of the contact hole is insufficient.

Conversely, CVD or ALD deposition techniques are more likely to provide a deposited metal layer exhibiting a superior step coverage as compared to PVD. However, when subsequently conducting annealing of these CVD or ALD metal layers, relatively high specific resistances of these metal silicide layers is likely to arise because of the CVD or ALD deposition techniques introduce residual impurities inside these deposited metal layers.

As a result, in the conventional art, it is difficult to form a metal silicide layer having a desired thickness and low specific resistance.

### SUMMARY OF THE INVENTION

Embodiments of the present invention are directed to a method for manufacturing a semiconductor device that can form a metal silicide layer having a desired thickness and low specific resistance.

A method for manufacturing of forming a metal silicide layer on a semiconductor device includes the step of, depositing, using PVD, a first metal layer on a silicon substrate formed with an interlayer dielectric having a contact hole; depositing, using either CVD and ALD, a second metal layer on the first metal layer; annealing the second metal layer and the first metal layer; and removing portions of the first and second metal layer that have not reacted during annealing.

Before the step of depositing the first metal layer, the method may further comprise the step of cleaning a surface of the silicon substrate which is exposed through the contact hole.

The steps of depositing the first and second metal layers are conducted in situ.

Each of the first metal layer and the second metal layer comprises a cobalt layer.

The cobalt layer is deposited using any one cobalt organic among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

Annealing is conducted using a rapid thermal annealing technique at a temperature of 450˜800° C.

Another method for manufacturing of forming a metal suicide layer on the semiconductor device includes the steps of depositing, using PVD, a first metal layer on a silicon substrate formed with an interlayer dielectric having a contact hole; depositing, using either CVD or ALD, a second metal layer on the first metal layer; primarily annealing the silicon substrate having a passivation layer, the second metal layer and the first metal layer; removing the passivation layer and portions of the second metal layer and the first metal layer that have not reacted during the primarily annealing step; and secondarily annealing the silicon substrate removed with the passivation layer and the portions of the second metal layer and the first metal layer which have not reacted during annealing to form a metal silicide layer at the bottom of the contact hole.

Before the step of depositing the first metal layer, the method may further comprise the step of cleaning a surface of the silicon substrate that is exposed through the contact hole.

The step of depositing the first metal layer and the step of depositing the second metal layer are conducted in situ.

Each of the first metal layer and the second metal layer comprises a cobalt layer.

The cobalt layer is deposited using any one cobalt organic among cobalt dicarbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

The passivation layer is formed as a single layer comprising a titanium layer or a titanium nitride layer. Alternately, the passivation layer may be formed as a stack structure comprising a titanium layer and a titanium nitride layer.

The primary annealing step is conducted using a rapid thermal annealing technique at a temperature of 400˜500° C.

The secondary annealing step is conducted as rapid thermal annealing technique at a temperature of 700˜800° C.

Another method for manufacturing of forming a metal silicide on a semiconductor device comprises the steps of: depositing, using PVD, a first metal layer on a silicon substrate formed with a gate having spacers on both sidewalls thereof and junction areas on both sides of the gate; depositing, using CVD and ALD, a second metal layer on the first metal layer; annealing the silicon substrate formed with the second metal layer and the first metal layer; and removing portions of the second metal layer and the first metal layer that have not reacted during the annealing step wherein leaving a metal silicide layer on the silicon substrate.

The gate has a hard mask layer formed thereon, wherein the hard mask layer comprises a nitride layer.

Before the step of depositing the first metal layer, the method further comprises the step of cleaning a surface of the silicon substrate formed with the gate having the spacers formed on both sidewalls thereof and the junction areas.

The step of depositing the first metal layer and the step of depositing the second metal layer are conducted in situ.

Each of the first metal layer and the second metal layer comprises a cobalt layer.

The cobalt layer is deposited using any one cobalt organic among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

The annealing step is conducted using a rapid thermal annealing technique at a temperature of 450˜800° C.

The method for manufacturing a metal silicide layer on a semiconductor device comprises the steps of depositing, using PVD, a first metal layer on a silicon substrate formed with a gate having spacers on both sidewalls thereof and junction areas on both sides of the gate; depositing, using either CVD and ALD, a second metal layer on the first metal layer; forming a passivation layer on the second metal layer; primarily annealing the silicon substrate formed with the passivation layer; removing the passivation layer and portions of the second metal layer and the first metal layer that have not reacted during the annealing step; and secondarily annealing the silicon substrate to form a metal silicide layer on the silicon substrate.

The gate has a hard mask layer formed thereon, wherein the hard mask layer comprises a nitride layer.

Before the step of depositing the first metal layer, the method may further comprise the step of cleaning a surface of the silicon substrate formed with the gate having the spacers formed on both sidewalls thereof and the junction areas.

The step of depositing the first metal layer and the step of depositing the second metal layer are conducted in situ.

Each of the first metal layer and the second metal layer comprises a cobalt layer.

The cobalt layer is deposited using any one cobalt organic among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

The passivation layer is may be formed as a single layer comprising a titanium layer or a titanium nitride layer. Alternately the passivation layer may be formed as a stack structure comprising a titanium layer and a titanium nitride layer.

The primary annealing step is conducted using a rapid thermal annealing technique at a temperature of 400˜500° C.

The secondary annealing is conducted using a rapid thermal annealing technique at a temperature of 700˜800° C.

### BRIEF DESCRIPTION OF THE DRAWINGS

FIGS. 1A through 1E are cross-sectional views illustrating the processes of a method for manufacturing a semiconductor device in accordance with a first embodiment of the present invention.

FIG. 2A is a TEM (transmission electron microscopy) photograph of a sample in which a CVD-Co layer was deposited after a PVD-Co layer was deposited. FIG. 2B is a graph showing the results of AES (Auger electron spectroscopy) analysis corresponding to the sample of FIG. 2B.

FIG. 3A is a view showing the results of XRD (X-ray diffraction) of a sample in which a CVD-Co layer was deposited subsequent to depositing a PVD-Co layer. FIG. 3B is a view showing the results of AES analysis corresponding to the sample of FIG. 3A.

FIG. 4A is a table of sheet resistance results as a function of temperature corresponding to a sample in which a CVD-Co layer was deposited after depositing a PVD-Co layer. FIG. 4B is a graph of sheet resistance results as a function of analysis corresponding the sample of FIG. 4A.

FIGS. 5A through 5F are cross-sectional views illustrating the processes of a method for manufacturing a semiconductor device in accordance with a second embodiment of the present invention.

FIGS. 6A through 6D are cross-sectional views illustrating the processes of a method for manufacturing a semiconductor device in accordance with a third embodiment of the present invention.

FIGS. 7A through 7E are cross-sectional views illustrating the processes of a method for manufacturing a semiconductor device in accordance with a fourth embodiment of the present invention.

### DESCRIPTION OF SPECIFIC EMBODIMENTS

In the present invention, a metal silicide layer is selectively formed by performing rapid thermal annealing (RTA) on a stack composed of a first metal layer formed using PVD and a second metal layer formed using CVD or ALD.

The metal silicide layer is formed using a metal layer composed of the first metal layer formed from using PVD and the second metal layer formed from using either CVD or ALD. The resultant metal silicide layer formed from a RTA technique yields an unexpectedly low specific resistance characteristic. When the metal is cobalt, the cobalt silicide layer can be formed to a desired thickness due to the second cobalt layer formed from either using CVD or ALD that yield an excellent step coverage characteristics even with a relatively high aspect ratio of a contact hole.

Conventionally, metal silicide layers are formed using a single layer deposition of the metal layer using either PVD or CVD. A problem arises as the aspect ratio of a contact holes increases, in that it becomes much more difficult to achieve adequate coverage of the metal silicide layer at the bottom of contact holes. Accordingly, the stability of the resultant metal silicide layers is likely to yield unacceptable contact resistances. That is, adequate step coverage brought about by PVD metal layer deposition within these high aspect ratio contact holes cannot be easily achieved at the very bottom of these high aspect ratio contact holes where that metal coverage is most needed. Even though CVD or ALD metal deposition techniques provide deposition techniques of achieving excellent coverage within these high aspect ratio contact holes, the resultant metal silicide is likely to exhibit an unacceptably high resistances. These high resistances are thought to be caused by impurities that remain in the metal layer made from using either the CVD or ALD techniques.

The present invention provides that the first metal layer is formed using PVD, and that the second metal layer is formed on the first metal layer using either CVD or ALD. Then, by conducting rapid thermal annealing technique on the stack of the first metal layer and the second metal layer, the metal silicide is subsequently formed. By exploiting the advantages of PVD and CVD or ALD, it is possible to form a metal silicide that exhibits a desired thickness and exhibits a low specific resistance within a high aspect ratio contact hole. As a result the resultant performance of a semiconductor device fabricated from the present invention can be improved so that they conform to the high integration design standards of modern day semiconductor devices.

Hereafter, specific embodiments of the present invention will be described in detail with reference to the attached drawings.

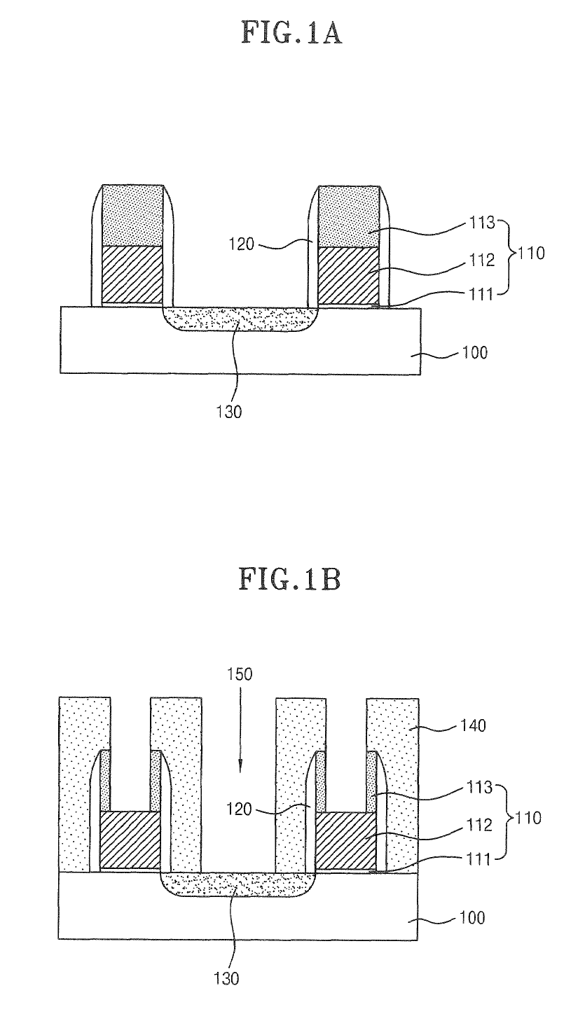

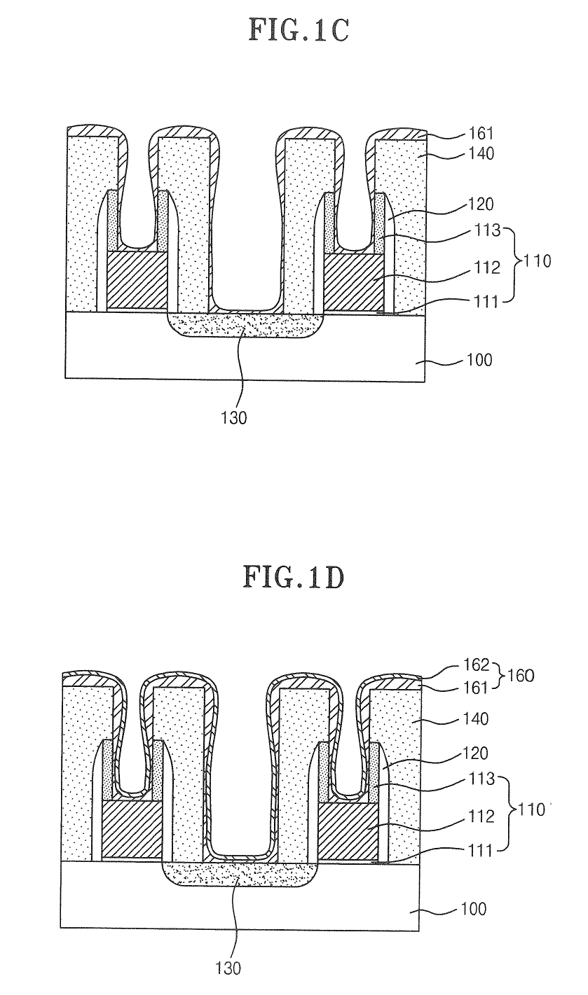

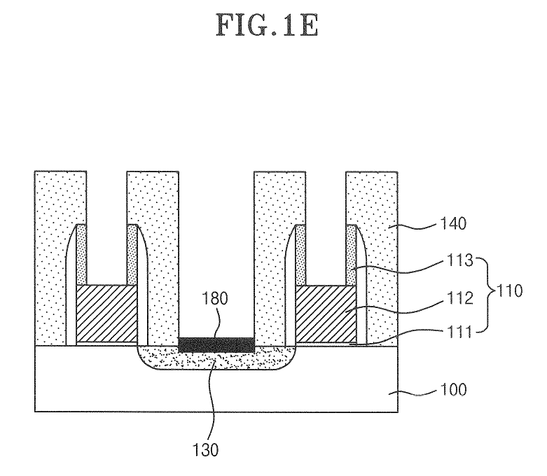

FIGS. 1A through 1E are cross-sectional views illustrating the processes of a method for manufacturing of a metal silicide layer on a semiconductor device in accordance with a first embodiment of the present invention.

Referring to FIG. 1A, a silicon substrate 100, which is divided into active regions and isolation regions (not shown), is prepared. An isolation layer (not shown) for delimiting the active regions is formed in the isolation regions of the silicon substrate 100 in accordance to well-known processes. Gates 110, in each of which a gate insulation layer 111, a gate electrode 112, and a hard mask layer 113 comprising a nitride layer are sequentially stacked, are formed in the active regions of the silicon substrate 100. The gate electrode 112 comprises the stack of a polysilicon layer and a metal-based layer or the single layer of a polysilicon layer. Gate spacers 120 are formed on both sidewalls of each gate 110 wherein each gate spacer 120 comprises an insulation layer formed as a single layer or as a stack having of at least two layers. Junction areas 130 are formed in the surface of the silicon substrate 100 on both sides of the gate 110 formed with the gate spacers 120 by conducting an impurity ion implantation process for the silicon substrate 100 formed with the gate spacers 120.

Referring to FIG. 1B, after depositing an interlayer dielectric 140 on the silicon substrate 100 to cover the gates 110, by CMPing (chemically and mechanically polishing) the interlayer dielectric 140, the surface of the interlayer dielectric 140 is planarized. By conducting a masking process and an etching process for the interlayer dielectric 140, a contact hole 150 is defined to expose the junction area 130 of the silicon substrate 100. In order to remove any native oxide that is produced while conducting the etching process for the interlayer dielectric 140, the surface of the silicon substrate 100 formed with the gates 110 and the junction areas 130 is cleaned.

Referring to FIG. 1C, a first cobalt layer 161 is deposited on the interlayer dielectric 140 including the contact hole 150 using a metallic material through PVD. The first cobalt layer 161 is deposited using any one cobalt organic compound among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

The first cobalt layer 161 is not easily deposited on the bottom of the contact hole 150 due to the poor step coverage characteristic of PVD. However, as the first cobalt layer 161 is deposited using PVD, it is possible to form a cobalt layer 161 having low specific resistance.

Referring to FIG. 1D, a second cobalt layer 162 is formed in situ on the first cobalt layer 161 using either CVD or ALD. The cobalt layer 160 comprising the stack of the first cobalt layer 161 and that of the second cobalt layer 162 is formed. The second cobalt layer 162 is deposited using any one cobalt organic compounds among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂]. Since the second cobalt layer 162 is deposited using CVD or ALD, an excellent step coverage is achieved. The second cobalt layer 162 can be easily deposited on the bottom of the contact hole 150 where the first cobalt layer 161 is poorly deposited.

Because the cobalt layer 160 comprises the stack of the first cobalt layer 161 formed using PVD and the second cobalt layer 162 formed using either CVD or ALD that can eventually be annealed into a cobalt silicide layer, it is possible to form a cobalt layer 160 that exhibits a low specific resistance property of to the first cobalt layer 161 and an excellent step coverage property of the second cobalt layer 162.

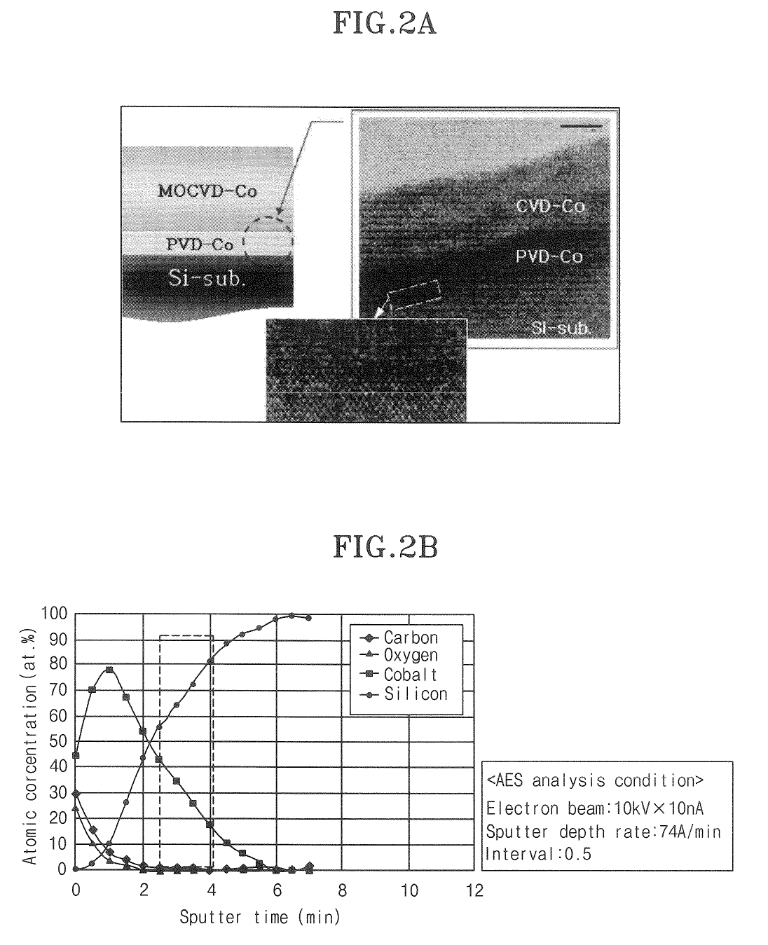

FIG. 2A is a TEM (transmission electron microscopy) photograph of and FIG. 2B is a graph showing the results of AES (Auger electron spectroscopy) analysis for a sample where a first cobalt layer is formed on a silicon substrate using PVD and a second cobalt layer is formed on the first cobalt layer using CVD in accordance to the present invention.

Referring to both FIGS. 2A and 2B, it is noted that no interlayer is formed at the interface between the first cobalt layer formed using PVD and the silicon substrate. Since no interlayer is formed at the interface between a subsequently formed cobalt silicide layer and the silicon substrate, the resultant structure can exhibit a typical sheet resistance.

Referring to FIG. 1E, the results of implementing the annealing step on the silicon substrate 100 having the second cobalt layer 162 and the first cobalt layer 161 are depicted. The annealing is conducted using a rapid thermal annealing technique at a temperature of 450˜800° C. By conducting the annealing, portions of the second cobalt layer 162 and the first cobalt layer 161 form at the bottom of the contact hole 150, and subsequently react with the junction area 130 of the silicon substrate 100 to form a stable cobalt suicide layer (CoSi₂) 180. Thereby the cobalt silicide layer (CoSi₂) 180 is selectively formed on the bottom of the contact hole 150. After removing any remaining portions of the second cobalt layer 162 and the first cobalt layer 161 that have not reacted during the annealing step, the cobalt silicide layer 180 remains.

When the gate electrode 112 is formed as a single layer of a polysilicon layer, annealing the cobalt silicide layer is also formed on the surface of the polysilicon layer constituting the gate electrode 112.

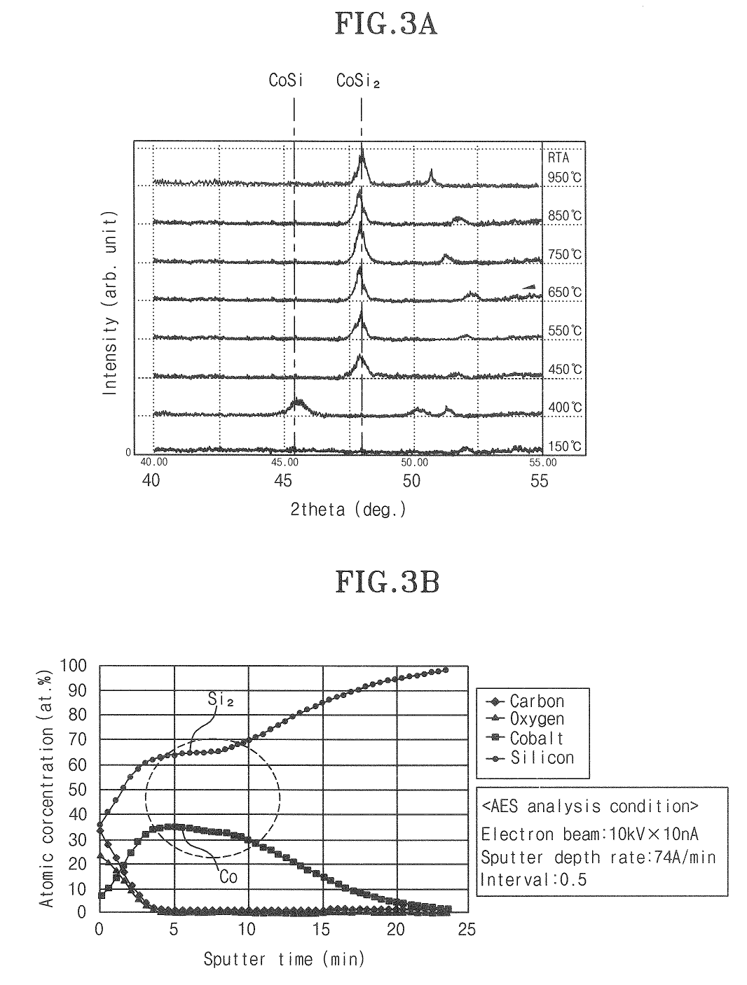

FIG. 3A shows XRD (X-ray diffraction) results as a function of annealing temperature and FIG. 3B graphically depicts an AES (Auger electron spectroscopy) sputtering time profile from a cobalt silicide layer (CoSi₂) RTA annealed at 650° C. formed in accordance to the present invention.

Referring to FIG. 3A, in the XRD analysis results, it is understood that the formation of a cobalt silicide layer (CoSi) starts at the temperature of about 400° C. and a stable cobalt silicide layer (CoSi₂) is formed at or above 450° C. It is important to note that in the present invention, the temperature at which the stable cobalt silicide layer (CoSi₂) is formed is 300° C. lower than depositing CoSi₂ through MOCVD (Metal Organic Chemical Vapor Deposition) of the conventional art.

Referring to FIG. 3B, the AES analysis results demonstrate that a cobalt silicide layer (CoSi₂) is formed when conducting rapid thermal annealing at the temperature of 650° C. In particular note that the Si is formed in an amount approximately double that of the amount of Co during the sputter time period of 3˜10 minutes. Accordingly, the AES analysis provides sufficient evidence that a cobalt silicide layer (CoSi₂) is formed on the silicon.

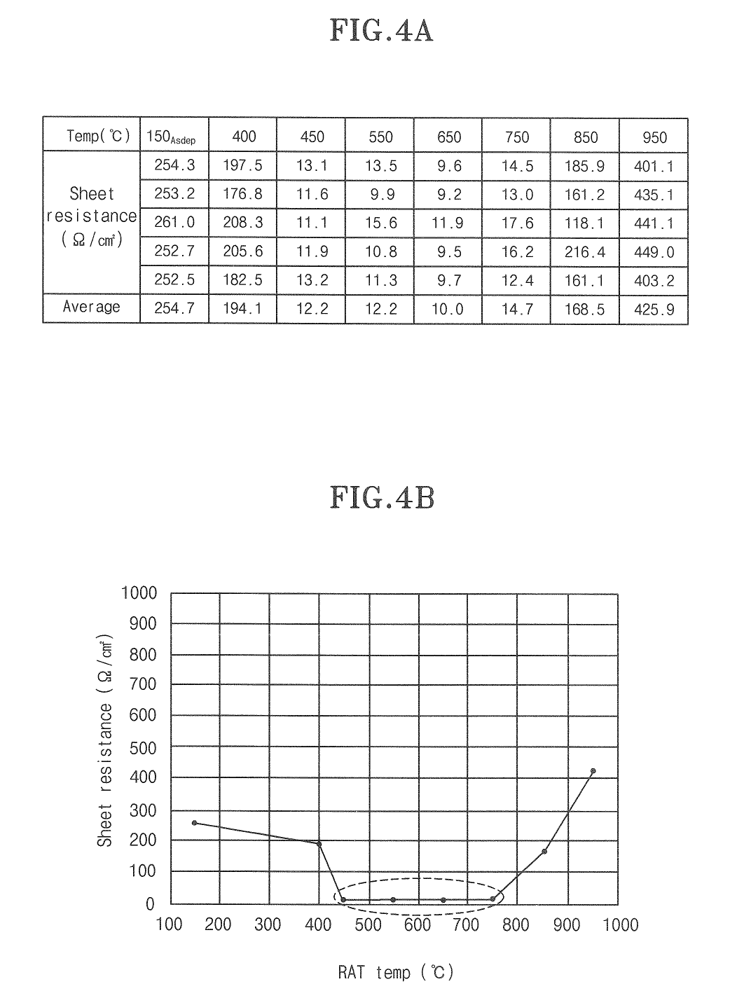

FIG. 4 is a table and a graph showing the sheet resistance of the cobalt silicide layer (CoSi₂) depending upon a temperature.

Referring to FIGS. 4A and 4B, the sheet resistance is shown to decrease when a cobalt silicide layer (CoSi₂) is formed at a temperature of 450∞750° C. Further, the sheet resistance of the cobalt suicide layer formed at the temperature of 650° C. is at a minimum.

Thereafter, while not shown in the drawings, by sequentially conducting a series of well-known subsequent processes, the manufacture of a metal silicide layer on a semiconductor device according to the first embodiment of the present invention can be completed.

As described above, in the present invention, a cobalt silicide layer is formed by conducting rapid thermal annealing on a cobalt layer comprising the stack cobalt layer composed of a first cobalt layer formed using PVD and a second cobalt layer formed using either CVD or ALD. Therefore, it is possible to form a cobalt layer that exhibits a low specific resistance due to the first cobalt layer formed using PVD and that exhibits an excellent step coverage due to the second cobalt layer formed using either CVD or ALD.

Accordingly, a process for forming a metal silicide layer using a cobalt layer that can conform to the demands associated with enhanced aspect ratios of the high integration of a semiconductor device can be realized. It is possible, using the present invention, to form a metal silicide layer having a desired thickness and low specific resistance for use in these enhanced aspect ratios of the high integration of a semiconductor device.

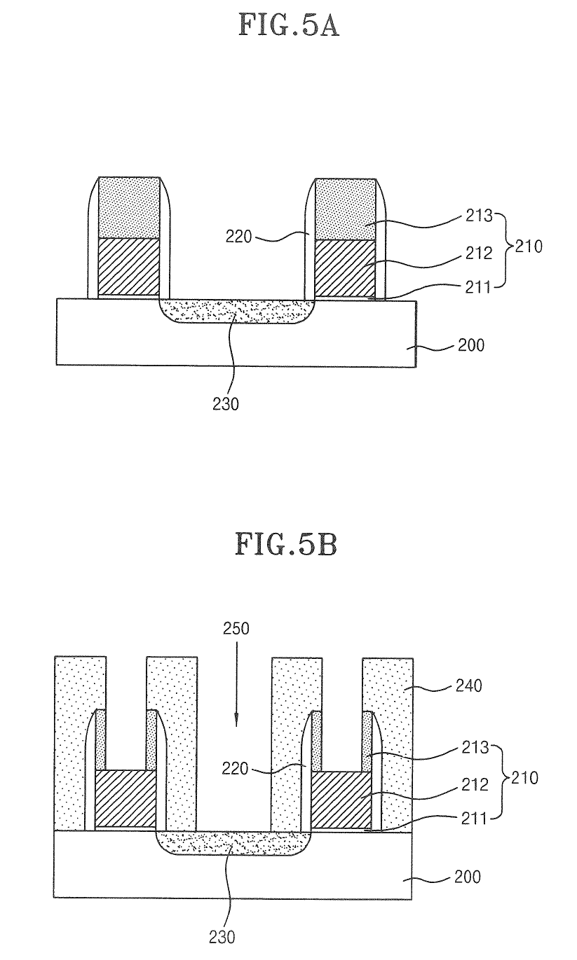

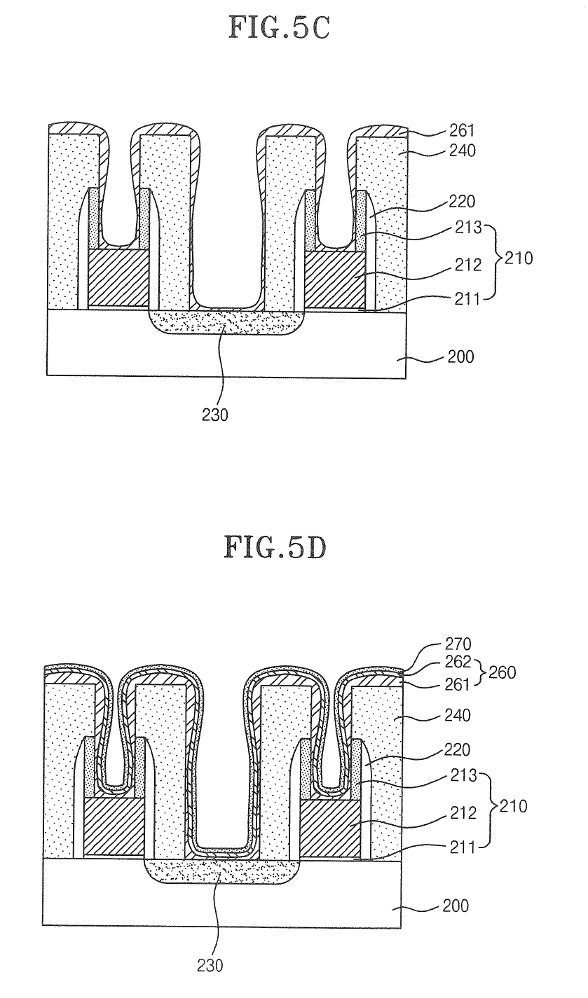

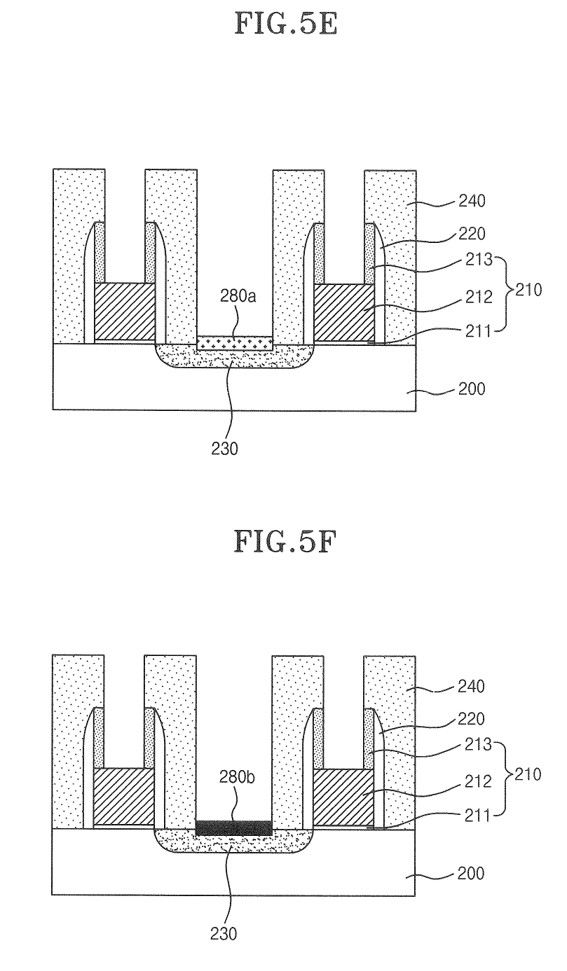

FIGS. 5A through 5F are cross-sectional views illustrating the processes of a method for manufacturing a semiconductor device in accordance with a second embodiment of the present invention.

Referring to FIG. 5A, a silicon substrate 200, is divided into active regions and isolation regions (not shown), is prepared. An isolation layer (not shown) for delimiting the active regions is formed in the isolation regions of the silicon substrate 200 in accordance to well-known processes. Gates 210 comprise a gate insulation layer 211, a gate electrode 212, and a nitride-based layer 213 that are sequentially stacked and are formed in the active regions of the silicon substrate 200. The gate electrode 212 comprises a stack of a polysilicon layer and a metal-based layer or the single layer of a polysilicon layer. Gate spacers 220 are formed on both sidewalls of each gate 210 wherein the gate spacers 220 comprise an insulation layer formed as a single layer or as a stack of at least two layers. Junction areas 230 are formed in the surface of the silicon substrate 200 on both sides of the gate 210 formed with the gate spacers 220 using an impurity ion implantation process.

Referring to FIG. 5B, after depositing an interlayer dielectric 240 on the silicon substrate 200 to cover the gates 210, the surface of the interlayer dielectric 240 is planarized using well known CMP processes. Using a masking process and an etching process on the interlayer dielectric 240, a contact hole 250 is subsequently defined that exposes the junction area 230 of the silicon substrate 200. In order to remove any native oxide that may have been produced during the etching process of the interlayer dielectric 240, the surface of the silicon substrate 200 formed with the gates 210 and the junction areas 230 are cleaned.

Referring to FIG. 5C, a first cobalt layer 261 is deposited on the interlayer dielectric 240 including the contact hole 250 using a metallic material through PVD. The first cobalt layer 261 is deposited using any one cobalt organic compounds among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂]. The first cobalt layer 261 may not necessarily be deposited in sufficiently high amounts at the bottom of the high aspect contact hole 250 due to the poor step coverage characteristics of PVD. However, it is possible to form a cobalt layer having low specific resistance for the remaining portions other than the bottom of the high aspect contact hole 250 when depositing the first cobalt layer 261 using PVD.

Referring to FIG. 5D, a second cobalt layer 262 is formed in situ on the first cobalt layer 261 using a metallic material using either CVD or ALD. Thereby, a cobalt layer 260 comprising a stack composed of the first cobalt layer 261 and the second cobalt layer 262 is formed. The second cobalt layer 262 is deposited using any one cobalt organic compound among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂]. Because the second cobalt layer 262 is deposited using either CVD or ALD then an excellent step coverage can be achieved for the second cobalt layer 262 even in the bottom of the high aspect contact hole 250 where the first cobalt layer 261 is lightly deposited.

A passivation layer 270 is formed on the second cobalt layer 262 to prevent the second cobalt layer 262 from being subsequently oxidated and for use in aiding in the development of a uniform silicide layer. The passivation layer 270 can be formed as a single layer comprising a titanium layer or a titanium nitride layer. Alternately, the passivation layer 270 can be formed as a stack structure composed of a titanium layer and a titanium nitride layer using any one of CVD, sputtering and ALD techniques.

Referring to FIG. 5E, primary annealing is conducted on the silicon substrate 200 that has the formed passivation layer 270, the second cobalt layer 262 and the first cobalt layer 261. The primary annealing is conducted as rapid thermal annealing technique at a temperature of 400˜500° C. By conducting the primary annealing, portions of the passivation layer 270, the second cobalt layer 262 and the first cobalt layer 261, which are formed on the bottom of the contact hole 250, react with the junction area 230 of the silicon substrate 200. As a result an amorphous cobalt silicide layer (CoSi) 280a is selectively formed on the bottom of the contact hole 250.

When the gate electrode 212 is formed as the single layer of a polysilicon layer, conducting the primary annealing results in the cobalt silicide layer also being formed on the surface of the polysilicon layer constituting the gate electrode 212.

After the primary annealing step, the passivation layer 270 and any remaining portions of the second cobalt layer 262 and the first cobalt layer 261 that have not reacted during the primary annealing are removed using a cleaning process.

Referring to FIG. 5F, after the passivation layer 270 and the portions of the second cobalt layer 262 and the first cobalt layer 261 that were not reacted during the primary annealing, a secondary annealing is conducted on the silicon substrate 200. The secondary annealing is conducted as a rapid thermal annealing technique at a temperature of 700˜800° C. By conducting the secondary annealing, the amorphous cobalt silicide layer (CoSi) 280a transforms into a crystallized cobalt silicide layer (CoSi₂), which is the final form of the cobalt silicide layer 280b formed at the bottom of the contact hole 250.

Thereafter, while not shown in the drawings, by sequentially conducting a series of well-known subsequent processes, the manufacture of the semiconductor device according to the second embodiment of the present invention is completed.

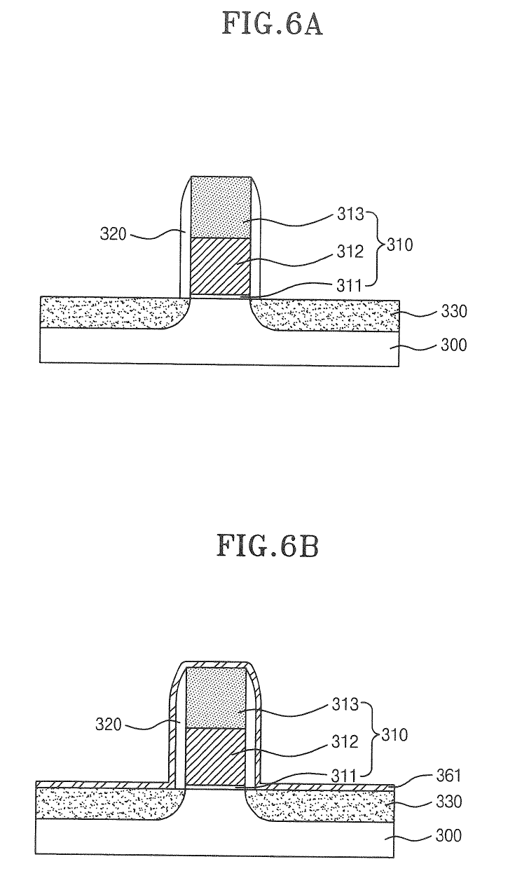

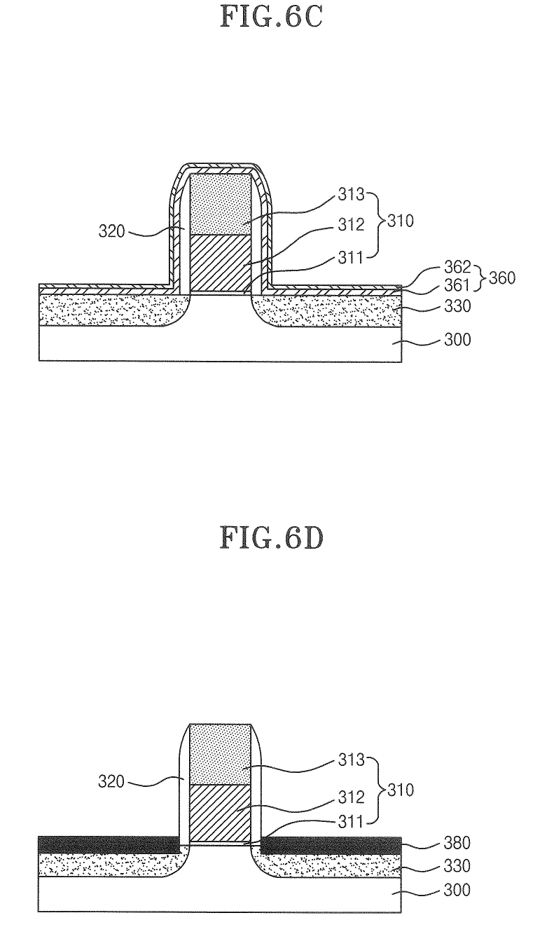

FIGS. 6A through 6D are cross-sectional views illustrating the processes of a method for manufacturing a semiconductor device in accordance with a third embodiment of the present invention.

Referring to FIG. 6A, a silicon substrate 300, which is divided into active regions and isolation regions (not shown), is prepared. An isolation layer (not shown) for delimiting the active regions is formed in the isolation regions of the silicon substrate 300 according to a well-known process. Each gate 310 comprises a gate insulation layer 311, a gate electrode 312, and a hard mask layer 213 composed of a nitride layer. Each gate 310 is formed in the active regions of the silicon substrate 300. The gate electrode 312 may comprise a stack of a polysilicon layer and a metal-based layer or comprise a single layer of a polysilicon layer. Gate spacers 320 may comprise an insulation layer formed as a single layer or may comprise a stack of at least two layers. The gate spacers 320 are formed on both sidewalls of each gate 310. Junction areas 330 are formed in the surface of the silicon substrate 300 on both sides of the gate 310 formed with the gate spacers 320 using an impurity ion implantation.

Referring to FIG. 6B, the surface of the silicon substrate 300, which is formed with the gate 310 and the junction areas 330, is cleaned. Then, a first cobalt layer 361 is deposited on the silicon substrate 300 including the gate 310 through PVD. The first cobalt layer 361 is deposited using any one cobalt organic compound among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂]. Since the first cobalt layer 361 is deposited using PVD, it is possible to form a cobalt layer having a low specific resistance.

Referring to FIG. 6C, a second cobalt layer 362 is formed in situ on the first cobalt layer 361 through CVD or ALD, and thereby, a cobalt layer 360 comprising the stack of the first cobalt layer 361 and the second cobalt layer 362 is formed. The second cobalt layer 362 is deposited using any one cobalt organic compound among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

Referring to FIG. 6D, annealing is conducted on the silicon substrate 300 formed with the second cobalt layer 362 and the first cobalt layer 361. The annealing is conducted as a rapid thermal annealing technique at a temperature of 450˜800° C. Annealing portions of the second cobalt layer 362 and the first cobalt layer 361, which are formed on the junction area 330 of the silicon substrate 300, react with the junction area 330 of the silicon substrate 300. As a result of this annealing step a stable cobalt silicide layer (CoSi₂) 380 is selectively formed on the surface of the junction area 330 of the silicon substrate 300. Subsequent to this annealing step, the remaining portions of the second cobalt layer 362 and the first cobalt layer 361, which have not reacted during annealing, are removed. Thereby a metal silicide layer, i.e., a cobalt silicide layer, is completely formed.

Thereafter, while not shown in the drawings, by sequentially conducting a series of well-known subsequent processes, the manufacture of the semiconductor device according to the third embodiment of the present invention is completed.

As described above, in the third embodiment of the present invention provides a means for making a cobalt silicide layer (CoSi₂) on the surface of the junction area 330 of the silicon substrate 300 before forming an interlayer dielectric. Accordingly, sheet resistances can be decreased. Thereby it is possible to subsequently decrease the contact resistance of a landing plug.

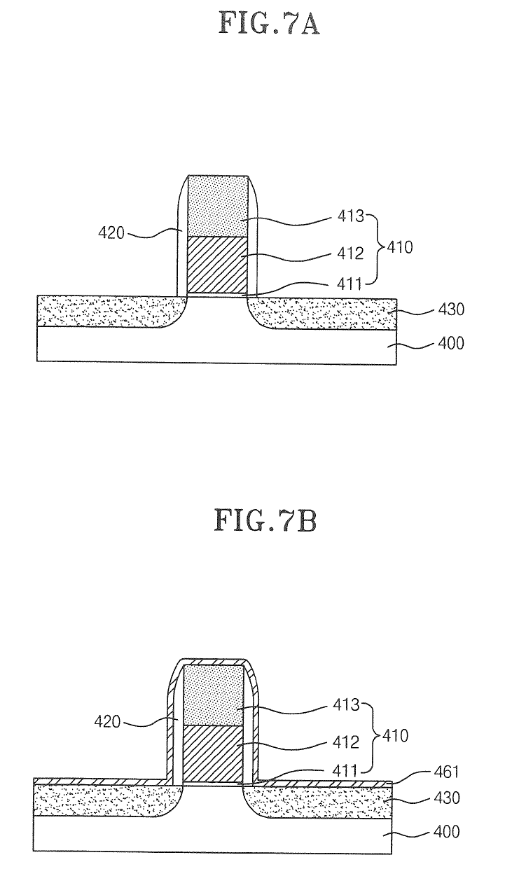

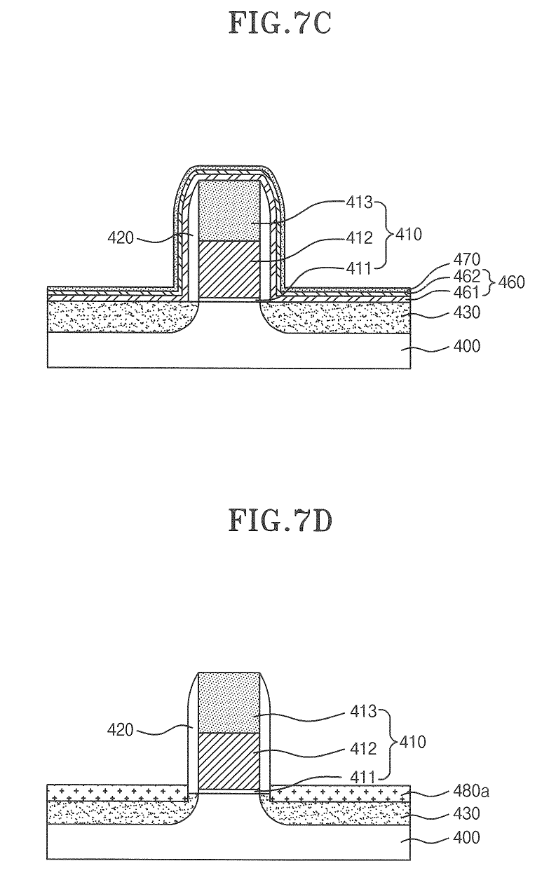

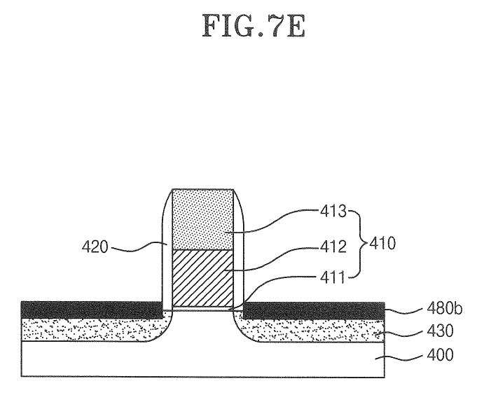

FIGS. 7A through 7E are sectional views illustrating the processes of a method for manufacturing a metal silicide on a semiconductor device in accordance with a fourth embodiment of the present invention.

Referring to FIG. 7A, a silicon substrate 400, which is divided into active regions and isolation regions (not shown), is prepared. An isolation layer (not shown) for delimiting the active regions is formed in the isolation regions of the silicon substrate 400 according to a well-known process. Each gates 410 comprises a gate insulation layer 411, a gate electrode 412, and a hard mask layer 413 composed of a nitride layer. Gates 410 are formed in the active regions of the silicon substrate 400. The gate electrode 412 may comprises either a stack structure of a polysilicon layer and a metal-based layer or the single layer structure of a polysilicon layer. Gate spacers 420 may comprise an insulation layer formed as a single layer or as a stack structure of at least two layers. Gate spacers 420 are formed on both sidewalls of each gate 410. Junction areas 430 are formed in the surface of the silicon substrate 400 on both sides of the gate 410 formed with the gate spacers using an impurity ion implantation process.

Referring to FIG. 7B, the surface of the silicon substrate 400 formed with the gate 410 and the junction areas 430, is cleaned. A first cobalt layer 461 is deposited on the silicon substrate 400 including the gate 410 through PVD. The first cobalt layer 461 is deposited using any one cobalt organic compound among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂]. Since the first cobalt layer 461 is deposited using PVD, resultant first cobalt layer 461 has a low specific resistance.

Referring to FIG. 7C, a second cobalt layer 462 is formed in situ on the first cobalt layer 461 through CVD or ALD, and thereby, a cobalt layer 460 comprising the stack of the first cobalt layer 461 and the second cobalt layer 462 is formed. The second cobalt layer 462 is deposited using any one cobalt organic compound among dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂]. A passivation layer 470 is formed on the second cobalt layer 462 to prevent the second cobalt layer 462 from being subsequently oxidated and for uniformly forming a silicide layer. The passivation layer 470 may be formed as a single layer comprising a titanium layer or a titanium nitride layer or as a stack structure composed of a titanium layer and a titanium nitride layer using any one of CVD, sputtering and ALD techniques.

Referring to FIG. 7D, primary annealing is conducted for the silicon substrate 400 formed with the passivation layer 470, the second cobalt layer 462 and the first cobalt layer 461. The primary annealing is conducted as a rapid thermal annealing technique at a temperature of 400˜500° C. By conducting the primary annealing, portions of the passivation layer 470, the second cobalt layer 462 and the first cobalt layer 461, which are formed on the junction area 430 of the silicon substrate 400, react with the junction area 430 of the silicon substrate 400 to selectively form an amorphous cobalt silicide layer (CoSi) 480a. Then, the passivation layer 470 and the remaining portions of the second cobalt layer 462 and the first cobalt layer 461, which have not reacted during the primary annealing, are then removed through a cleaning process.

Referring to FIG. 7E, subsequent to removing with the passivation layer 470 and the portions of the second cobalt layer 462 and the first cobalt layer 461 which have not reacted during the primary annealing, secondary annealing is conducted for the silicon substrate 400. The secondary annealing is conducted as a rapid thermal annealing technique at a temperature of 700˜800° C. By conducting the secondary annealing, the amorphous cobalt silicide layer (CoSi) 480a is transformed into a crystallized cobalt silicide layer (CoSi₂). As a result this final cobalt silicide layer 480b is formed on the surface of the junction area 430 of the silicon substrate 400.

Thereafter, while not shown in the drawings, by sequentially conducting a series of well-known subsequent processes, the manufacture of the semiconductor device according to the fourth embodiment of the present invention is completed.

As is apparent from the above description, in the present invention, a cobalt silicide layer is formed using a cobalt layer comprising the stack of a first cobalt layer formed through PVD and a second cobalt layer formed through CVD or ALD. Accordingly, the present invention provides a process for forming a metal silicide layer using a cobalt layer capable of conforming to the high integration of a semiconductor device. It is therefore possible to form a metal silicide layer having a desired thickness and a desired low specific resistance. Thereby the present invention provides improved fabrication characteristics for manufacturing high integrated semiconductor devices.

Although specific embodiments of the present invention have been described for illustrative purposes, those skilled in the art will appreciate that various modifications, additions and substitutions are possible, without departing from the scope and the spirit of the invention as disclosed in the accompanying claims.

What is claimed is:

1. A method for manufacturing a metal suicide layer on a semiconductor device, the method comprising the steps of:
depositing, using physical vapor deposition (PVD), a first metal layer on a silicon substrate having an interlayer dielectric with a contact hole;
depositing, using either chemical vapor deposition (CVD) or atomic layer deposition (ALD), a second metal layer on the first metal layer;
annealing the second metal layer and the first metal layer to form the metal silicide layer; and
removing portions of the first and second metal layers that did not form into the metal silicide layer during the annealing step.

2. The method according to claim 1, further comprises the step of cleaning a surface of the silicon substrate exposed through the contact hole, wherein the cleaning step performed before the step of depositing the first metal layer.

3. The method according to claim 1, wherein the step of depositing the first metal layer and the step of depositing the second metal layer are conducted in situ.

4. The method according to claim 1, wherein the first metal layer comprises cobalt and the second metal layer comprises cobalt.

5. The method according to claim 4, wherein the first and second metal layers are deposited using any one cobalt organic compounds selected from the group consisting of dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetra-cobalt dodecacarbonyl [Co₄(CO)₁₂].

6. The method according to claim 1, wherein annealing is conducted as a rapid thermal annealing process at a temperature of 450° C. to 800° C.

7. A method for manufacturing a metal silicide layer on a semiconductor device, the method comprising the steps of:
depositing, using physical vapor deposition (PVD), a first metal layer on a silicon substrate formed with an interlayer dielectric having a contact hole;
depositing, using either chemical vapor deposition (CVD) or atomic layer deposition (ALD), a second metal layer on the first metal layer;
forming a passivation layer on the second metal layer;
primarily annealing the passivation layer, the second metal layer and the first metal layer;
removing the passivation layer and portions of the first and second metal layers that did not react to form amorphous metal silicide layer during primarily annealing step; and
secondarily annealing the amorphous metal silicide layer.

8. The method according to claim 7 further comprises the step of cleaning a surface of the silicon substrate exposed through the contact hole wherein the cleaning step performed before the step of depositing the first metal layer.

9. The method according to claim 7, wherein the step of depositing the first metal layer and the step of depositing the second metal layer are conducted in situ.

10. The method according to claim 7, wherein the first metal layer comprises cobalt and the second metal layer comprises cobalt.

11. The method according to claim 10, wherein the first and second metal layers are deposited using any one cobalt organic compounds selected from the group consisting of dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅Co(CO)₂], and tetracobalt dodecacarbonyl [Co₄(CO)₁₂].

12. The method according to claim 7, wherein the passivation layer is formed as a single layer comprising titanium or titanium nitride, or wherein the passivation layer is formed as a stack layer comprising titanium and titanium nitride.

13. The method according to claim 7, wherein the primary annealing step is conducted using rapid thermal annealing at a temperature of 400° C. to 500° C.

14. The method according to claim 7, wherein the secondary annealing step is conducted using rapid thermal annealing at a temperature of 700° C. to 800° C.

15. A method for manufacturing a metal silicide layer on a semiconductor device, the method comprising the steps of:
depositing, using physical vapor deposition (PVD), a first metal layer on a silicon substrate formed with a gate having spacers on both sidewalls thereof and junction areas on both sides of the gate;
depositing, using either chemical vapor deposition (CVD) or atomic layer deposition (ALD), a second metal layer on the first metal layer;
annealing the first and second metal layers to form the metal silicide layer; and
removing portions of the first and second metal layers which have not reacted during annealing, therein forming a metal silicide layer on the silicon substrate.

16. The method according to claim 15, wherein the gate has a hard mask layer formed thereon, the hard mask layer comprises a nitride layer.

17. The method according to claim 15 further comprises the step of cleaning a surface of the silicon substrate formed with the gate having the spacers formed on both sidewalls thereof and the junction areas, wherein the cleaning step is performed before depositing the first metal layer.

18. The method according to claim 15, wherein the step of depositing the first metal layer and the step of depositing the second metal layer are conducted in situ.

19. The method according to claim 15, wherein the first metal layer comprises cobalt and the second metal layer comprises cobalt.

20. The method according to claim 19, wherein the first and second metal layers are deposited using any one cobalt organic compound selected from the group consisting of dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

21. The method according to claim 15, wherein annealing step is conducted using rapid thermal annealing at a temperature of 450° C. to 800° C.

22. A method for manufacturing a metal silicide layer on a semiconductor device, the method comprising the steps of:
depositing, using physical vapor deposition (PVD), a first metal layer on a silicon substrate formed with a gate having spacers on both sidewalls thereof and junction areas on both sides of the gate;
depositing, using chemical vapor deposition (CVD) or atomic layer deposition (ALD), to form a second metal layer on the first metal layer;
forming a passivation layer on the second metal layer;
primarily annealing the silicon substrate which is formed with the passivation layer, the first metal layer, and the second metal layer to react a portion of the first and second metal layers;
removing the passivation layer and portions of the first and second metal layers which have not reacted during the annealing step; and
secondarily annealing the reacted first and second metal layers to form a metal silicide layer on the silicon substrate.

23. The method according to claim 22, wherein the gate having a hard mask layer formed thereon, the hard mask layer comprises a nitride layer.

24. The method according to claim 22 further comprises the step of cleaning a surface of the silicon substrate formed with the gate having the spacers formed on both sidewalls thereof and the junction areas, wherein the cleaning step performed prior to depositing the first metal layer.

25. The method according to claim 22, wherein the step of depositing the first metal layer and the step of depositing the second metal layer are conducted in situ.

26. The method according to claim 22, wherein the first metal layer comprises cobalt and the second metal layer comprises cobalt.

27. The method according to claim 26, wherein the first and second metal layers are deposited using any one cobalt organic compounds selected from the group consisting of dicobalt carbonyl [Co₂(CO)₈], cobalt acetylacetonate [Co(CH₃COCHCOCH₃)₂], bis cyclopentadienyl cobalt [(C₅H₅)₂Co], cobalt tricarbonyl nitrosyl [Co(CO)₃NO], cyclopentadienyl cobalt dicarbonyl [C₅H₅CO(CO)₂], and tetracobalt dodecacarbonyl [Co₄(CO)₁₂].

28. The method according to claim 22, wherein the passivation layer is formed as a single layer comprising titanium layer or titanium nitride, alternatively the passivation layer is a stacked layer comprising titanium and titanium nitride.

29. The method according to claim 22, wherein primary annealing is conducted as rapid thermal annealing at a temperature of 400° C. to 500° C.

30. The method according to claim 22, wherein secondary annealing is conducted as rapid thermal annealing at a temperature of 700° C. to 800° C.
